(19) United States
(12) Patent Application Publication
(10) Pub. No.: US 2012/0098011 A1
(43) Pub. Date: Apr. 26, 2012

(54) ORGANIC LIGHT EMITTING DIODE DEVICE

(76) Inventors: Hongseok CHOI, Daejeon (KR); Hwakyung Kim, Gimpo-si (KR); Changje Sung, Goyang-si (KR); Younseok Kam, Seoul (KR)

(21) Appl. No.: 13/278,734

(22) Filed: Oct. 21, 2011

(30) Foreign Application Priority Data
Oct. 22, 2010 (KR) 10-2010-0103569

(51) Int. Cl. H01L 33/60

(52) U.S. Cl. 257/98; 257/40; 257/E33.072

(57) ABSTRACT

An organic light emitting device is disclosed. An organic light emitting device according to one embodiment of the present invention comprises a reflection layer; an anode disposed on the reflection layer; a first stack disposed on the anode and comprising a first light emission layer; a charge generation layer disposed on the first stack; a second stack disposed on the charge generation layer and comprising a second light emission layer; and a cathode disposed on the second stack, the first light emission layer being disposed within about 120 to about 180 nm from a surface of the reflection layer and the second light emission layer being disposed within about 320 to about 380 nm from the surface of the reflection layer.

This application claims the benefit of Korean Patent Application Nos. 10-2010-0103569 filed on October 22, which is hereby incorporated by reference in its entirety.

### BACKGROUND

1. Field

The present disclosure relates to an organic light emitting diode device. More specifically, the present disclosure relates to an organic light emitting diode device capable of improving luminous efficiency.

2. Related Art

Recently, flat panel displays (FPDs) are becoming more importance with widespread use of multimedia data. To meet the demand, various types of flat panel displays are commercialized, including liquid crystal display (LCD), plasma display panel (PDP), field emission display (FED), organic light emitting device, and so on.

In particular, an organic light emitting device provides a high response speed, which is 1 ms or below, consumes low power and comprises a self-glowing material. The organic light emitting device has no limit on field of view; accordingly, the organic light emitting device is attractive as a video display medium irrespective of the size of a device to be implemented. Also, since the organic light emitting device can be produced at low temperature and its related manufacturing process is simple employing a conventional semiconductor manufacturing process, the organic light emitting device is getting attention as a next generation flat panel display device.

An organic light emitting device comprises a light emission layer between an anode and a cathode. Holes provided from the anode and electrons from the cathode are combined in the light emission layer, thereby forming excitons, which are electron-hole pairs. The organic light emitting device emits light due to the energy generated as the excitons return to the ground state.

Organic light emitting devices are being developed in various types of structure. Among others, a white organic light emitting device has a structure such that a red, a green, and a blue light emission layer form a stack structure.

The white organic light emitting device of the stack structure has a problem due to a short life expectancy of the blue light emission layer and subsequent low color stability; and relatively high driving voltage. To solve the problem above, more layers are added, making the original structure more complex and inappropriate for mass production.

### SUMMARY

An organic light emitting device comprises a reflection layer; an anode disposed on the reflection layer; a first stack disposed on the anode and comprising a first light emission layer; a charge generation layer disposed on the first stack; a second stack disposed on the charge generation layer and comprising a second light emission layer; and a cathode disposed on the second stack, the first light emission layer being disposed within about 120 to about 180 nm from a surface of the reflection layer and the second light emission layer being disposed within about 320 to about 380 nm from the surface of the reflection layer.

### BRIEF DESCRIPTION OF THE DRAWINGS

The accompany drawings, which are included to provide a further understanding of the invention and are incorporated on and constitute a part of this specification illustrate embodiments of the invention and together with the description serve to explain the principles of the invention.

FIG. 1 illustrates an organic light emitting device according to one embodiment of the present invention;

FIG. 2 is a simplified view of an organic light emitting device according to one embodiment of the present invention;

FIG. 3 illustrates light intensity according to the position of light emission layers of an organic light emitting device according to a first embodiment of the present invention;

FIG. 4 illustrates an organic light emitting device according to a second embodiment of the present invention;

FIG. 5 is a simplified view of an organic light emitting device according to a second embodiment of the present invention;

FIGS. 6a and 6b illustrate light intensity according to the position of light emission layers of an organic light emitting device according to a second embodiment of the present invention; and

FIG. 7 illustrates a light emission spectrum according to a viewing angle of an organic light emitting device manufactured according to an experimental example of the present invention.

### DETAILED DESCRIPTION OF EXEMPLARY EMBODIMENTS

Reference will now be made in detail embodiments of the invention examples of which are illustrated in the accompanying drawings.

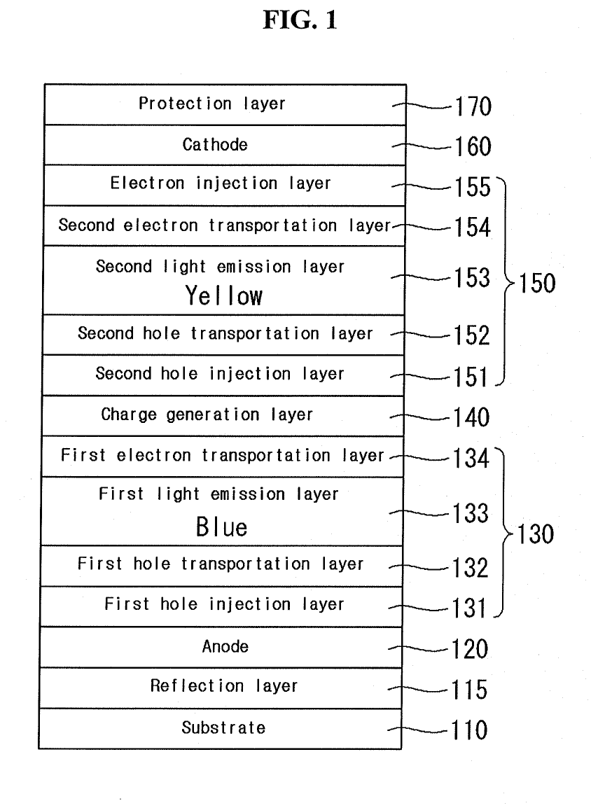

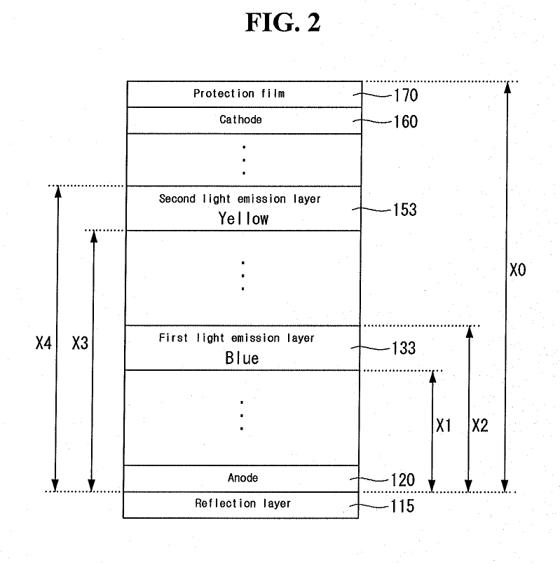

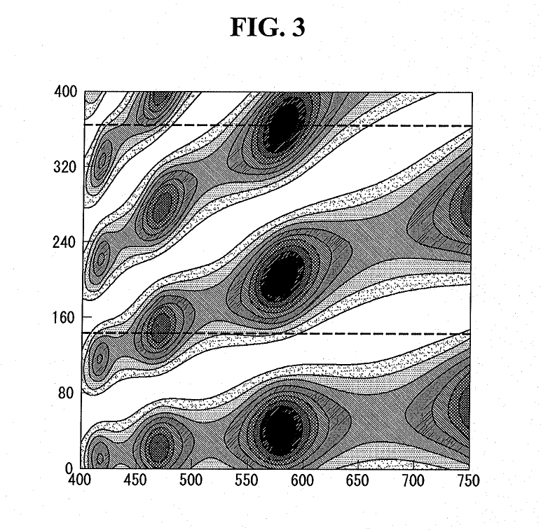

FIG. 1 illustrates an organic light emitting device according to one embodiment of the present invention; FIG. 2 is a simplified view of an organic light emitting device according to one embodiment of the present invention; and FIG. 3 illustrates light intensity according to the position of light emission layers of an organic light emitting device according to a first embodiment of the present invention.

With reference to FIG. 1, an organic light emitting device 100 according to a first embodiment can be a white organic light emitting device incorporating yellow and blue rays.

An organic light emitting device 100 according to a first embodiment of the present invention comprises an anode 120 on a substrate 110, a first stack 130 incorporating a first light emission layer 133 disposed on the anode 120, a charge generation layer 140 disposed on the first stack 130, a second stack 150 incorporating a second light emission layer 153 disposed on the charge generation layer 140, and a cathode disposed on the second stack.

The substrate 110 can be made from transparent glass, plastic, or a conductive material.

The anode 120 can be a transparent electrode. The anode 120 can be composed of ITO (Indium Tin Oxide), IZO (Indium Zinc Oxide), or ZnO (Zinc Oxide).

A reflection layer 115 can be further included between the substrate 110 and the anode electrode 120. The reflection layer 115 reflects light toward an upper part and can be composed of aluminum (Al), silver (Ag), or Nickel (Ni) in a lower part of the anode 120.

The first stack 130 disposed on the anode 120 can comprise a first light emission layer 133 emitting blue rays. The first stack 130 comprises only a blue light emission layer as the first light emission layer 134 and emits only blue rays, improving blue color stability.

The first light emission layer 133 is a light emission layer emitting blue rays; the first light emission layer 133 can be a mix of one host with fluorescent blue dopants.

As one example, the first light emission layer 134 can be a mix of a host material such as AND(9,10-di(2-naphthyl)anthracene) or DPVBi(4,4′-bis(2,2-diphenylethen-1-yl)-diphenyl) with fluorescent blue dopant such as 1,6-Bis(diphenylamine)pyrene or TBPe(tetrakis(t-butyl)perylene).

Also, the fluorescent blue dopant can be deep blue or sky blue dopant. Examples of the deep blue dopant include 4′-N,N-diphenylaminostyryl-triphenyl(DPA-TP); 2,5,2′,5′-2,5,2′,5′-tetrastyryl-biphenyl: TSB; anthracene derivatives; p-bis(p-N,N-diphenyl-aminostyryl)benzene; or phenylcyclopentadiene.

The first stack 130 further comprises a first hole injection layer 131 formed between the anode 120 and the first light emission layer 133; a first hole transportation layer 132; and a first electron transportation layer 134 formed between the first light emission layer 133 and the charge generation layer 140.

The hole injection layer 131 facilitates injection of holes to the first light emission layer 134 from the anode 120; and is composed of one or more selected from a group consisting of CuPc (copper phthalocyanine), PEDOT (poly(3,4)-ethylenedioxythiophene), PANI(polyaniline) and NPD(N,N-dinaphthyl-N,N′-diphenyl benzidine); but is not limited to the above.

The first hole transportation layer (HTL) 132 facilitates transport of holes; and is composed of one or more selected from a group consisting of NPD(N,N-dinaphthyl-N,N′-diphenyl benzidine), TPD(N,N′-bis-(3-methylphenyl)-N,N′-bis-(phenyl)-benzidine), s-TAD and MTDATA(4,4′,4″-Tris(N-3-methylphenyl-N-phenyl-amino)-triphenylamine); but are not limited to the above.

The first electron transportation layer (ETL) 134 facilitates transport of electrons; and is composed of one or more selected from a group consisting of Alq3(tris(8-hydroxyquinolino)aluminum), PBD, TAZ, spiro-PBD, BAlq, and SAlq; but is not limited to the above.

Meanwhile, the charge generation layer (CGL) 140 disposed on a first stack 130 can be composed of a double layer or a single layer.

To be more specific, if the charge generation layer 140 comprises a double layer, the charge generation layer 140 can be a PN junction charge generation layer joining N-type charge generation layer and P-type charge generation layer. At this time, the PN junction charge generation layer 140 generates charges or separates them into holes and electrons; and injects the charges into the individual light emission layer. In other words, the N-type charge generation layer provides electrons for the first light emission layer 133 adjacent to the anode while the P-type charge generation layer provides holes to the second light emission layer 153 adjacent to the cathode 160, by which luminous efficiency of an organic light emitting device incorporating multiple light emission layers can be further improved and at the same time, driving voltage can be lowered.

The P-type charge generation layer can be composed of metal or organic material doped with P-type dopant. Here, the metal can be one or an alloy consisting of two or more selected from a group consisting of Al, Cu, Fe, Pb, Zn, Au, Pt, W, In, Mo, Ni, and Ti. Also, P-type dopant and host used for organic material doped with the P-type can employ conventional materials. For example, the P-type dopant can be one selected from a group consisting of tetrafluore-7,7,8,8-tetracyanoquinodimethane (F4-TCNQ), derivative of tetracyanoquinodimethane, iodine, FeCl3, FeF3, and SbCl5. Also, the host can be one selected from a group consisting of N,N′-di(naphthalen-1-yl)-N,N-diphenyl-benzidine (NPB), N,N′-diphenyl-N,N′-bis(3-methylphenyl)-1,1-biphenyl-4,4′-diamine(TPD) and N,N′,N′-tetranaphthyl-benzidine (TNB).

The N-type charge generation layer can be composed of metal or organic material doped with N-type. At this time, the metal can be one selected from a group consisting of Li, Na, K, Rb, Cs, Mg, Ca, Sr, Ba, La, Ce, Sm, Eu, Tb, Dy, and Yb. Also, N-type dopant and host used for organic material doped with the N-type can employ conventional materials. For example, the N-type dopant can be alkali metal, alkali metal compound, alkali earth metal, or alkali earth metal compound. More specifically, the N-type dopant can be one selected from a group consisting of Cs, K, Rb, Mg, Na, Ca, Sr, Eu and Yb. The host material can be one selected from a group consisting of tris(8-hydroxyquinoline)aluminum, triazin, hydroxyquinoline derivative, benzazol derivative, and silole derivative.

If the charge generation layer 140 is a single layer, the charge generation layer 140 can be composed of the P-type or the N-type charge generation layer.

The second stack 150 disposed on the charge generation layer 140 can comprise the second light emission layer 153 emitting yellow rays. The second light emission layer 153 can comprise yellow dopants for one host or comprise red and green dopants for one host.

As one example, if the second light emission layer 153 comprises yellow dopants for one host, the same material used for the host of the first light emission layer 133 can be employed as a host and blue dopant while Irpq2acac (bis(phenylquinoline) iridium acetylacetonate) is used as yellow phosphorescent dopant.

On the other hand, if the second light emission layer 153 comprises blue, red, and green dopant, Ir(piq)2acac (bis(phenyl isoquinoline) iridium acetylacetonate) can be employed as the red phosphorescent dopant for the host while Irppy3(tris(phenyl pyridine) iridium) can be used as green phosphorescent dopant.

The second stack 150 can further comprise a second hole transportation layer 151 and a second hole transportation layer 152 formed between the charge generation layer 140 and the second light emission layer 153; and a second electron transportation layer 154 and an electron injection layer 155 formed between the second light emission layer 153 and the cathode 160.

Since the second hole injection layer 151, the second hole transportation layer 152, and the second electron transportation layer 154 are the same as the first hole injection layer 131, the first electron transportation layer 132, and the first electron transportation layer 134, related description will be omitted.

The electron injection layer (EIL) 155 facilitates injection of electrons and is composed of Alq3(tris(8-hydroxyquinolino)aluminum), PBD, TAZ, Spiro-PBD, BAlq, or SAlq, but is not limited to the above. The electron injection layer 155 can be composed of metal halide compound; for example, the electron injection layer 155 can be composed of one or more selected from a group consisting of MgF2, LiF, NaF, KF, RbF, CsF, FrF, and CaF2, but is not limited to the above.

The cathode 160 can be composed of transparent materials such that light emitted from the light emission layers 133, 153 comes out through the front surface. As one example, the cathode 160 can be composed of ITO (Indium Tin Oxide), IZO (Indium Zinc Oxide), or ZnO (Zinc Oxide).

A protection film 170 is disposed on the cathode 160. The protection film 170 protects elements below and can be composed of an organic or an inorganic film but is not limited to the above.

In an organic light emitting device composed as above according to one embodiment of the present invention, each light emission layer can be disposed as follows.

With reference to FIG. 2, the first light emission layer 133 of the present invention can be disposed being separated from the surface of the reflection layer 115 by a first distance X1 and can be disposed at a position not going beyond a second distance X2. At this time, the first distance X1 can be about 120 nm while the second distance X2 is about 180 nm.

In other words, the first light emission layer 133 of the present invention emitting blue rays can be disposed within about 120 to about 180 nm from the surface of the reflection layer 115.

The second light emission layer 153 of the present invention can be disposed being separated from the surface of the reflection layer 115 by a third distance X3 and can be disposed at a position not going beyond a fourth distance X4. At this time, the third distance X3 can be 320 nm while the fourth distance X4 380 nm.

In other words, the second light emission layer 153 of the present invention emitting yellow rays can be disposed within about 320 to about 380 nm from the surface of the reflection layer 115.

Based on the positional relationship between the first light emission layer 133 and the second light emission layer 153, it can be seen that the maximum luminous efficiency can be obtained when the distance X0 from an organic light emitting device of the present invention, namely, the surface of the reflection layer 115 to the protection film 170 ranges from about 480 to about 580 nm.

To be more specific, with reference to FIG. 3 illustrating light intensity according to the position of the first 133 and the second light emission layer 153 of the present invention, the vertical axis denotes distance by which light emission layers are separated from the surface of the reflection layer while the horizontal axis denotes wavelength of light.

The area where reinforcement of light is largest corresponds to the center region of a contour map. The farther from the center area, the weaker becomes the reinforcement of light and the area with the deepest color corresponds to where light is cancelled out.

With reference to FIG. 3, the area where intensity of blue rays with a wavelength of 470 nm appears large corresponds to the area separated by about 150 nm from the surface of the reflection layer. Also, the area where intensity of yellow rays with a wavelength of 580 nm appears large corresponds to the area separated from the surface of the reflection layer by about 350 nm.

Accordingly, by disposing the first light emission layer 133 emitting blue rays within a range of about 120 to about 180 nm from the surface of the reflection layer 115 and the second light emission layer 153 emitting yellow rays within a range of about 320 to about 380 nm from the surface of the reflection layer 115, luminous intensity at each wavelength can be maximized and accordingly, luminous efficiency of white rays can be improved.

As described above, an organic light emitting device according to the first embodiment of the present invention provides an advantage that white rays can show the maximum luminous efficiency as the position of the first and the second light emission layer is adjusted.

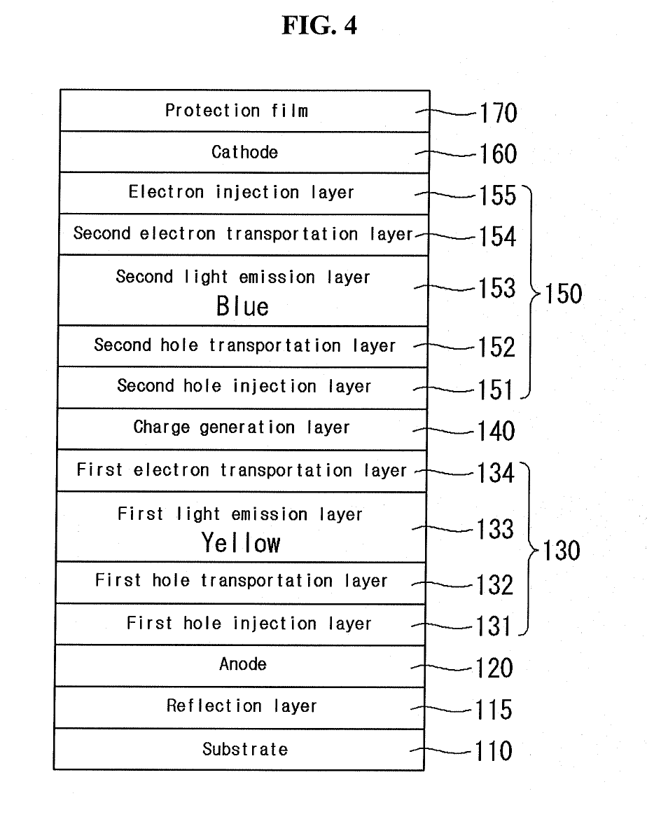

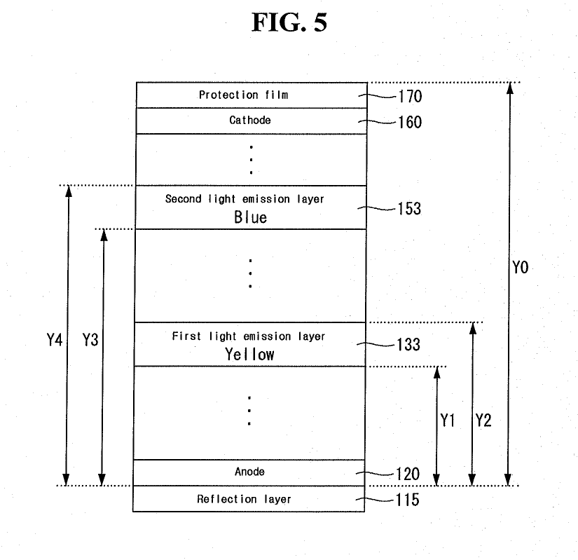

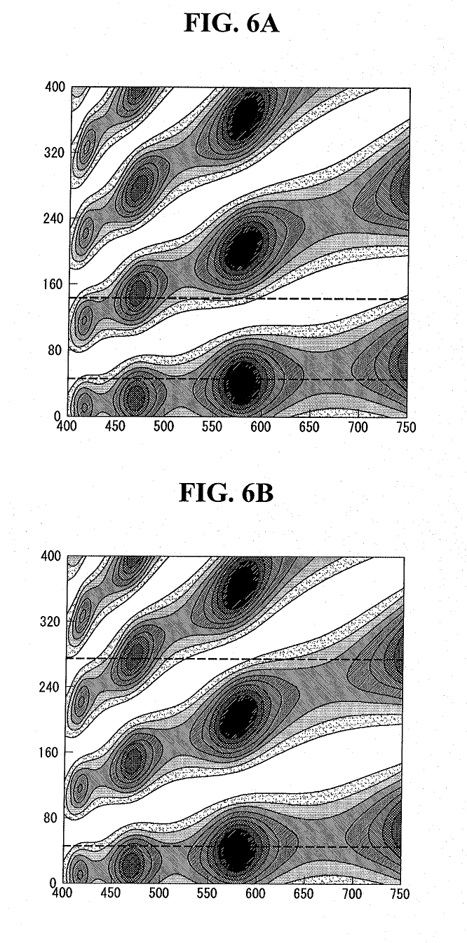

FIG. 4 illustrates an organic light emitting device according to a second embodiment of the present invention; FIG. 5 is a simplified view of an organic light emitting device according to a second embodiment of the present invention; FIGS. 6a and 6b illustrate light intensity according to the position of light emission layers of an organic light emitting device according to a second embodiment of the present invention.

In what follows, the same constituting elements as used in the organic light emitting device according to the first embodiment use the same drawing symbols and repeated description will be omitted.

With reference to FIG. 4, an organic light emitting device 100 according to a second embodiment can be a white organic light emitting device incorporating yellow and blue rays.

An organic light emitting device 100 according to a second embodiment of the present invention comprises an anode 120 on a substrate 110, a first stack 130 incorporating a first light emission layer 133 disposed on the anode 120, a charge generation layer 140 disposed on the first stack 130, a second stack 150 incorporating a second light emission layer 153 disposed on the charge generation layer 140, and a cathode disposed on the second stack.

The first stack 130 disposed on the anode 120 can comprise a first light emission layer 133 emitting yellow rays. The first stack 130 comprises only a yellow light emission layer as the first light emission layer 134 and emits only yellow rays, improving yellow color stability.

The first light emission layer 133 is a light emission layer emitting yellow rays and is the same as the second light emission layer 153 which is the yellow light emission layer of the first embodiment; therefore, the corresponding description will be omitted.

The first stack 130 further comprises a first hole injection layer 131 formed between the anode 120 and the first light emission layer 133; a first hole transportation layer 132; and a first electron transportation layer 134 formed between the first light emission layer 133 and the charge generation layer 140.

The second tack 150 disposed on the charge generation layer 140 can comprise a second light emission layer 153 emitting blue rays. The second light emission layer 153 is the same as the first light emission layer 133 of the first embodiment emitting blue rays; therefore, the corresponding description will be omitted.

The second stack 150 can further comprise a second hole transportation layer 151 and a second hole transportation layer 152 formed between the charge generation layer 140 and the second light emission layer 153; and a second electron transportation layer 154 and an electron injection layer 155 formed between the second light emission layer 153 and the cathode 160.

In an organic light emitting device composed as above according to one embodiment of the present invention, each light emission layer can be disposed as follows.

With reference to FIG. 5, the first light emission layer 133 of the present invention emitting yellow rays can be disposed being separated from the surface of the reflection layer 115 by a first distance Y1 and can be disposed at a position not going beyond a second distance Y2. At this time, the first distance Y1 can be 20 nm while the second distance Y2 is 80 nm.

In other words, the first light emission layer 133 of the present invention emitting yellow rays can be disposed within 20 to 80 nm from the surface of the reflection layer 115.

The second light emission layer 153 of the present invention emitting blue rays can be disposed being separated from the surface of the reflection layer 115 by a third distance Y3 and can be disposed at a position not going beyond a fourth distance Y4. At this time, the third distance Y3 can be about 120 nm or about 250 nm while the fourth distance Y4 about 180 nm or about 330 nm.

In other words, the second light emission layer 153 of the present invention emitting blue rays can be disposed within 120 to 180 nm or within about 250 to about 330 nm from the surface of the reflection layer 115.

Based on the positional relationship between the first light emission layer 133 and the second light emission layer 153, it can be seen that the maximum luminous efficiency can be obtained when the distance Y0 from an organic light emitting device of the present invention, namely, the surface of the reflection layer 115 to the protection film 170 ranges from about 480 to about 580 nm.

More specifically, with reference to FIG. 6a illustrating light intensity according to the position of the first 133 and the second light emission layer 153 of the present invention, the area where intensity of yellow rays with a wavelength of 580 nm appears large corresponds to the area separated by about 40 nm from the surface of the reflection layer. Also, the area where intensity of blue rays with a wavelength of 470 nm appears large corresponds to the area separated from the surface of the reflection layer by about 150 nm.

With reference to FIG. 6b, the area where intensity of yellow rays with a wavelength of 580 nm appears large corresponds to the area separated by about 40 nm from the surface of the reflection layer. Also, the area where intensity of blue rays with a wavelength of 470 nm appears large corresponds to the area separated from the surface of the reflection layer by about 280 nm.

Accordingly, by disposing the first light emission layer 133 emitting yellow rays within a range of 20 to 80 nm from the surface of the reflection layer 115 and the second light emission layer 153 emitting blue rays within a range of 120 to 180 nm or within a range of about 250 to about 330 nm from the surface of the reflection layer 115, luminous intensity at each wavelength can be maximized and accordingly, luminous efficiency of white rays can be improved.

As described above, an organic light emitting device according to the second embodiment of the present invention provides an advantage that white rays can show the maximum luminous efficiency as the position of the first and the second light emission layer is adjusted.

In what follows, an experimental example according to one embodiment of the present invention will be described. However, the experimental example described below is just one embodiment of the present invention and the present invention is not limited to the experimental example described below.

### Experimental Example

ITO glass is patterned in such a way that the size of a light emitting area amounts to 2 mm×2 mm and the patterned ITO glass is washed. The substrate is loaded into a vacuum chamber and a base pressure of 1×10-6 torr is applied to the chamber. The reflection layer is coated by Ag with a thickness of 1000 Å and anode ITO is coated with a thickness of 100 Å. On top of ITO, the first hole injection layer DNTPD is coated with a thickness of 50 Å and the first hole transportation layer NPD is coated with a thickness of 1500 Å. Vacuum coating with blue fluorescent dopant Ir(pFCNp)3 is applied for the host ADN(9,10-di(2-naphthyl)anthracene), forming the first light emission layer with thickness of 250 Å.

And the first electron transportation layer Alq3 is coated with a thickness 200 Å and N-type charge generation layer Li is coated with a thickness 100 Å and P-type charge generation layer Al is coated with 150 Å.

Next, the second hole injection layer DNTPD is coated with a thickness of 100 Å and the second hole transportation layer NPD is coated with a thickness of 1200 Å. Vacuum coating with green fluorescent dopant Ir(ppy)3 and red phosphorous dopant Ir(mnapy)3 is applied for the host CBP, forming the second light emission layer with a thickness of 250 Å. Next, the second electron transportation layer Alq3 is coated with a thickness of 250 Å; the electron injection layer LiF is coated with a thickness of 10 Å; and the cathode ITO is coated with a thickness of 1200 Å, manufacturing an organic light emitting device.

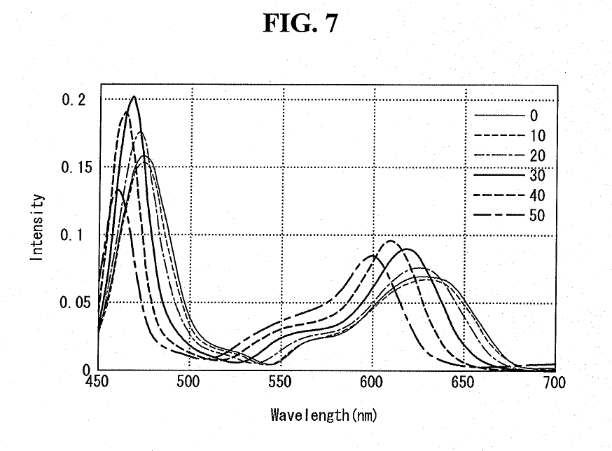

Light emission spectrum of an organic light emitting device manufactured according to the experimental example was measured according to a viewing angle and the measured result is shown in FIG. 7. Luminous efficiency and color coordinates according to a viewing angle were measured and the measured result is shown in Table 1.

TABLE 1

| | Driving | Luminous | | | | |
|---|---|---|---|---|---|---|
| Viewing | voltage | efficiency | | Quantum | Color | |
| angle (°) | (V) | Cd/A | Lm/W | efficiency | coordiant | |
| 0 | 11.7 | 21.9 | 5.9 | 17.8 | 0.325 | 0.235 |
| 10 | 11.6 | 21.0 | 5.7 | 17.0 | 0.327 | 0.234 |
| 20 | 11.6 | 22.4 | 6.1 | 17.2 | 0.333 | 0.233 |
| 30 | 11.6 | 25.1 | 6.8 | 17.3 | 0.341 | 0.236 |
| 40 | 11.6 | 27.7 | 7.5 | 16.5 | 0.349 | 0.255 |
| 50 | 11.6 | 28.3 | 7.7 | 14.6 | 0.354 | 0.299 |

With reference to Table 1, the organic light emitting device according to the experimental example of the present invention shows that luminous efficiency at normal direction where the viewing angle is 0 degrees is 21.9 Cd/A while color coordinates are 0.325 and 0.235.

And as shown in FIG. 7, an optical spectrum at the front of an organic light emitting device according to the experimental example of the present invention reveals that desired peaks appear at short wavelengths and long wavelengths.

As described above, an organic light emitting device according to embodiments of the present invention optimizes the position of the first and the second light emission layer according to the color of emitted rays, improving luminous efficiency and color coordinate characteristics of the organic light emitting device emitting white rays.

The foregoing embodiments and advantages are merely exemplary and are not to be construed as limiting the present invention. The present teaching can be readily applied to other types of apparatuses. The description of the foregoing embodiments is intended to be illustrative, and not to limit the scope of the claims. Many alternatives, modifications, and variations will be apparent to those skilled in the art. In the claims, means-plus-function clauses are intended to cover the structures described herein as performing the recited function and not only structural equivalents but also equivalent structures. Moreover, unless the term “means” is explicitly recited in a limitation of the claims, such limitation is not intended to be interpreted under 35 USC 112 (6).

What is claimed is:

1. An organic light emitting device, comprising:
a reflection layer;
an anode disposed on the reflection layer;
a first stack disposed on the anode and comprising a first light emission layer;
a charge generation layer disposed on the first stack;
a second stack disposed on the charge generation layer and comprising a second light emission layer; and
a cathode disposed on the second stack,
the first light emission layer being disposed within about 120 to about 180 nm from a surface of the reflection layer and the second light emission layer being disposed within about 320 to about 380 nm from the surface of the reflection layer.

2. The organic light emitting device of claim 1, wherein the first light emission layer emits blue rays and the second light emission layer emits yellow rays.

3. The organic light emitting device of claim 1, wherein the first stack further comprises a first hole injection layer and a first hole transportation layer formed between the anode and the first light emission layer; and
a first electron transportation layer formed between the first light emission layer and the charge generation layer.

4. The organic light emitting device of claim 1, wherein the second stack further comprises a second hole injection layer and a second hole transportation layer formed between the charge generation layer and the second light emission layer; and
a second electron transportation layer and an electron injection layer formed between the second light emission layer and the cathode.

5. The organic light emitting device of claim 1, wherein a protection film on the cathode is further included and distance from a surface of the reflection layer to the protection film ranges from about 480 to about 580 nm.

6. An organic light emitting device, comprising:
a reflection layer;
an anode disposed on the reflection layer;
a first stack disposed on the anode and comprising a first light emission layer;
a charge generation layer disposed on the first stack;
a second stack disposed on the charge generation layer and comprising a second light emission layer; and
a cathode disposed on the second stack,
the first light emission layer being disposed within 20 to 80 nm from a surface of the reflection layer and the second light emission layer being disposed within about 120 to about 180 nm or within 250 to 330 nm from the surface of the reflection layer.

7. The organic light emitting device of claim 6, wherein the first light emission layer emits yellow rays and the second light emission layer emits blue rays.

8. The organic light emitting device of claim 6, wherein the first stack further comprises a first hole injection layer and a first hole transportation layer formed between the anode and the first light emission layer; and
a first electron transportation layer formed between the first light emission layer and the charge generation layer.

9. The organic light emitting device of claim 6, wherein the second stack further comprises a second hole injection layer and a second hole transportation layer formed between the charge generation layer and the second light emission layer; and
a second electron transportation layer and an electron injection layer formed between the second light emission layer and the cathode.

10. The organic light emitting device of claim 6, wherein a protection film on the cathode is further included and distance from a surface of the reflection layer to the protection film ranges from about 480 to about 580 nm.
